(19) United States
(12) Patent Application Publication
(10) Pub. No.: US 2015/0207460 A1
(43) Pub. Date: Jul. 23, 2015

(54) PULSE INJECTION CRYSTAL OSCILLATOR

(71) Applicant: THE REGENTS OF THE UNIVERSITY OF MICHIGAN, Ann Arbor, MI (US)

(72) Inventors: Dongmin Yoon, Ann Arbor, MI (US); David T. Blaauw, Ann Arbor, MI (US); Dennis Sylvester, Ann Arbor, MI (US); Scott Hanson, Austin, TX (US)

(21) Appl. No.: 14/379,426

(22) PCT Filed: Feb. 15, 2013
(86) PCT No.: PCT/US13/26376

§ 371 Date: Aug. 18, 2014

Related U.S. Application Data
(60) Provisional application No. 61/600,067, filed on Feb. 17, 2012.

(51) Int. Cl. H03B 5/36

(52) U.S. Cl. CPC H03B 5/36

(57) ABSTRACT

An improved oscillation driver circuit for use in an integrated circuit in combination with an oscillation element. An amplification element is adapted to receive an oscillator output, and to generate an amplified oscillator output. A pulse generator receives the amplified oscillator output and generates positive and negative pulsed outputs substantially in phase with the oscillator output. A driver element is adapted to drive the oscillator input in response to the pulsed outputs.

### CROSS-REFERENCE TO RELATED APPLICATIONS

This application claims priority to U.S. Provisional Application Ser. No. 61/600,067 filed 17 Feb. 2012 (“Parent Provisional”), and hereby claims benefit of the filing dates thereof pursuant to 37 CFR §1.78(a)(4). The subject matter of the Parent Provisional, in its entirety, is expressly incorporated herein by reference.

### FIELD

The present disclosure relates generally to oscillator driver circuits used in integrated circuits, and, in particular, to low power oscillator driver circuits.

### BACKGROUND

In general, in the descriptions that follow, we will italicize the first occurrence of each special term of art that should be familiar to those of ordinary skill in the art of low power current reference design. In addition, when we first introduce a term that we believe to be new or that we will use in a context that we believe to be new, we will bold the term and provide the definition that we intend to apply to that term. In addition, throughout this description, we will sometimes use the terms assert and negate when referring to the rendering of a signal, signal flag, status bit, or similar apparatus into its logically true or logically false state, respectively, and the term toggle to indicate the logical inversion of a signal from one logical state to the other. Alternatively, we may refer to the mutually exclusive boolean states as logic_{—}0 and logic_{—}1. Of course, as is well known, consistent system operation can be obtained by reversing the logic sense of all such signals, such that signals described herein as logically true become logically false and vice versa. Furthermore, it is of no relevance in such systems which specific voltage levels are selected to represent each of the logic states.

Power consumption has become a key problem for circuit designers with the proliferation of battery-powered devices. Circuit topologies that support power reduction are extremely valuable in extending battery life. Oscillator driver circuits are present in virtually all integrated circuit (“IC”) since all digital electronics require synchronization clocks for proper operation.

For the purposes of this specification, we intend the term oscillation element to mean any arrangement of active or passive electronic components, including, for example, transistors, resistors, capacitors, inductors, crystals, surface acoustic wave (“SAW”) devices, and the like, that, when coupled to a suitable driver circuit, will generate a substantially periodic, oscillatatory output signal. We also intend the term amplification element to mean any arrangement of active or passive electronic components, including, for example, transistors, resistors, capacitors and the like, that, when coupled to a suitable input signal source, will present a high-impedance to that source, and, optionally: either increase the power of the received signal, including for the purposes of this definition, by a 1-to-1 power ratio; or provide a voltage shift from a first voltage domain to a second voltage domain higher than the first voltage domain; or both. Further, we intend the term driver element to mean any arrangement of active or passive electronic components, including, for example, transistors, resistors, capacitors, and the like, that, when coupled to a suitable input signal source, will generate output currents substantially sufficient to sustain oscillation. In all of these definitions, we intend to subsume other typical support circuits, including, for example, power sources and related power conditioning resources, as will be known to those in the art of IC design and operation.

Shown in FIG. 1 is a prior art oscillator driver circuit 10 comprising: a crystal-based oscillation element 12 having an oscillation input 14 and an oscillation output 16; and a complementary-metal-oxide-semiconductor (“CMOS”) driver 18 having a driver input 20 adapted to be connected to the oscillation output 16 and a driver output 22 adapted to be connected to the oscillation input 14. In a typical instantiation, the driver circuit 18 is integrated onto the primary IC, and the crystal-based oscillation element 12 is off-chip; however, some or all of the components other than the crystal per se may be integrated as desired.

All analog oscillator driver circuits of which we are aware, including the example shown in FIG. 1, draw significant cross-bar current around zero-crossing transitions. Further, as noted in our Parent Provisional, attempts to reduce the operating voltage range of prior art designs to the sub-threshold range tend to result in unstable operation.

Given the wide use of oscillation drivers and the significant power demands of these circuits, we submit that what is needed is an improved method and apparatus for an ultra□low power oscillation driver. Such a method and apparatus are important for use in power sensitive systems such as battery-powered electronics.

### SUMMARY

In accordance with one embodiment of our disclosure, we provide a driver circuit for an oscillation element having an oscillator input and an oscillator output. The driver circuit comprises an amplification element and a driver element. The amplification element has: an amplification input adapted to be coupled to the oscillator output; and an amplification output. The driver element having: a driver input coupled to the amplification output; and a driver output adapted to be coupled to the oscillator input.

In one other embodiment, we provide a method we prefer for driving an oscillation element adapted to receive an oscillator input signal and to generate an oscillator output signal. Our method comprising three basic steps. First, we receive the oscillator output signal. Second, we generate an amplified output signal in response to the received oscillator output signal. Third, we drive the oscillator input signal in response to the amplified oscillator output signal.

We submit that each of these embodiments of our disclosure provide for an ultra-low power oscillation driver circuit and method, the performance being generally comparable to the best prior art techniques while consuming substantially less power than known implementation of such prior art techniques.

### DRAWINGS

Our disclosure may be more fully understood by a description of certain example embodiments in conjunction with the attached drawings in which:

FIG. 1 illustrates, in schematic form, an embodiment of a prior art oscillation driver circuit;

FIG. 2 illustrates, in block diagram form, one embodiment of an oscillation driver circuit constructed in accordance with our disclosure;

FIG. 3 illustrates, in block diagram form, one embodiment of an amplification element constructed in accordance with our disclosure;

FIG. 4 illustrates, in wave form, one possible phase relationship of the pulsed outputs of the pulse generator illustrated in FIG. 3;

FIG. 5 illustrates, in block diagram form, one other embodiment of an amplification element constructed in accordance with our disclosure;

FIG. 6 illustrates, in block diagram form, yet another embodiment of an amplification element constructed in accordance with our disclosure;

FIG. 7 illustrates, in schematic form, an amplification element specially adapted for use in oscillation driver circuits constructed in accordance with our disclosure;

FIG. 8 illustrates, in schematic form, a driver element specially adapted for use in oscillation driver circuits constructed using pulsed amplification elements as shown by way of example in FIG. 3, FIG. 5, and FIG. 6; and

FIG. 9 illustrates, in schematic form, a pulse generator specially adapted for use in oscillation driver circuits constructed using pulsed amplification elements as shown by way of example in FIG. 3, FIG. 5, and FIG. 6.

In the drawings, similar elements will be similarly numbered whenever possible. However, this practice is simply for convenience of reference and to avoid unnecessary proliferation of numbers, and is not intended to imply or suggest that our disclosure requires identity in either function or structure in the several embodiments.

### DETAILED DESCRIPTION

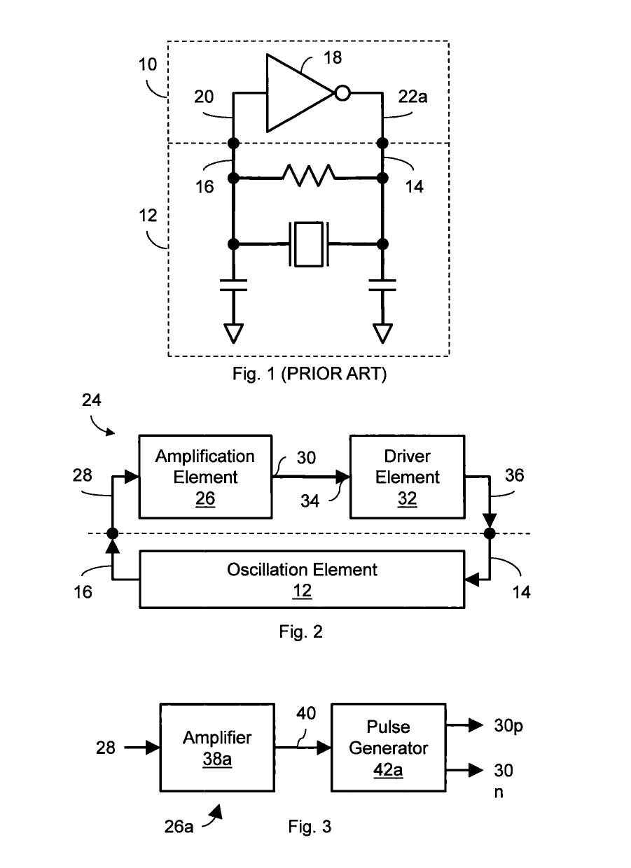

Shown in FIG. 2 is one embodiment of an oscillation driver circuit 24 constructed in accordance with our disclosure. As illustrated, an amplification element 26 has an amplification input 28 adapted to be coupled to the oscillator output 16 (see, generally, FIG. 1), and an amplification output 30. A driver element 32 has a driver input 34 coupled to the amplification output 30, and a driver output 36 adapted to be coupled to the oscillator input 14 (see, generally, FIG. 1). In operation, the amplification element 26 receives the oscillator output signal on amplification input 28, and generates on amplification output 30 an amplified output signal in response to the received oscillator output signal. The driver element 32 receives the amplified output signal on driver input 34 and drives on the driver output 36 the oscillator input signal in response to the amplified oscillator output signal.

In accordance with our disclosure, the amplification element 26 receives the oscillation output signal in a first voltage domain and generates the amplification output in a second voltage domain. The second voltage domain may be characterized as having a higher voltage swing than that of the first voltage domain. Preferably, the driver element 32 receives the amplification output in the second voltage domain, and generates the driver output 36 in the first voltage domain. This arrangement substantially improves the transconductance of the output stage of driver element 32 when the first voltage domain is sub-threshold.

The oscillation driver circuit 24 can operate in two or more different voltage domains. The oscillator 12 and the driver element 32 can operate in the smallest voltage domain, denoted for example by V_{DD-L} (515 mV) and V_{SS-L} (415 mV). The voltage across this domain is too small for the other circuits to reliably operate; other circuits, such as the pulse generator described below, may operate in a middle voltage domain, denoted for example by V_{DD-M} (660 mV) and V_{SS-M} (265 mV). Input signals to the driver element 32 can swing full rail, denoted for example by V_{DD-H} (940 mV) and V_{SS-H} ((OV), to provide high transconductance. While specific values are provided for the voltage domains, it is readily understood that other values fall within the scope of this disclosure.

The oscillation driver circuit 24 uses an amplifier stage, combined with separate voltage domains for the amplifier stage and the driver stage. It increases the input voltage amplitude to the driver circuit and improves device transconductance. This decouples the oscillator amplitude from the driver stage input amplitude and allows lower oscillation operation, thereby reducing power loss in the crystal itself. Furthermore, to address the losses in the driver, pulse mode charge injection may be used where the driver is only enabled for a short duration when the driver output is near the supply rail. This avoids driver conditions where both high current and high voltage exist across the driver, thereby reducing driver loss significantly.

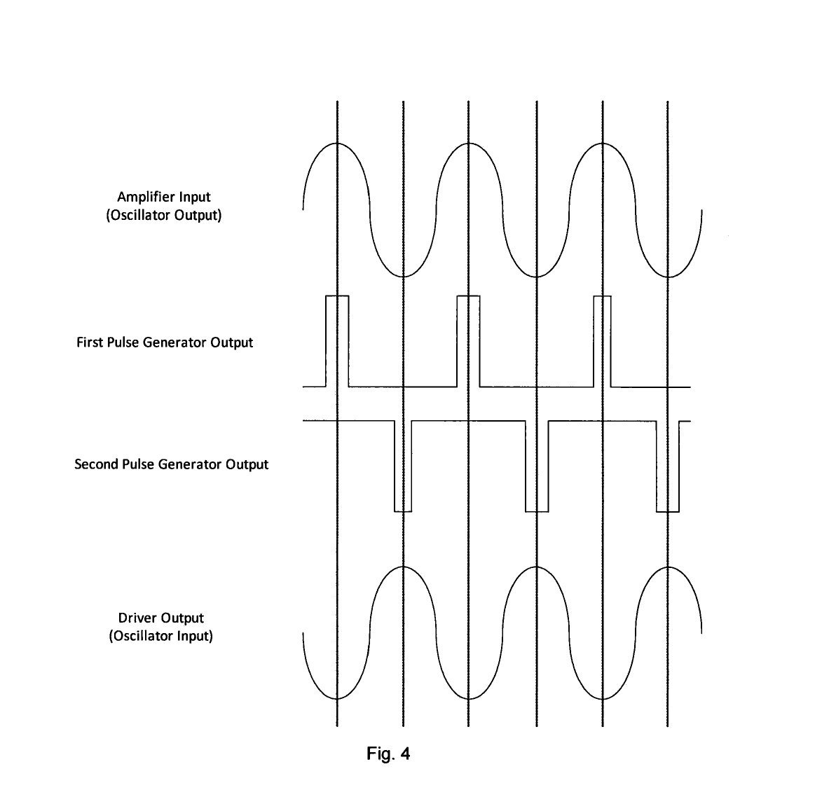

Shown in FIG. 3 is one embodiment of the amplification element 26 constructed in accordance with our disclosure. In this embodiment, an amplifier 38a is adapted to receive the oscillator output on amplification input 28, and to generate an amplified oscillator output on amplifier output 40. A pulse generator 42a receives the amplified oscillator output and generates positive pulsed output 30p and negative pulsed output 30n. Preferably, each positive pulsed output 30p is substantially in phase with a respective positive phase of the amplified oscillator output 40, and each negative pulsed output 30n is substantially in phase with a respective negative phase of the amplified oscillator output 40. One example of such a phase relationship is shown in FIG. 4.

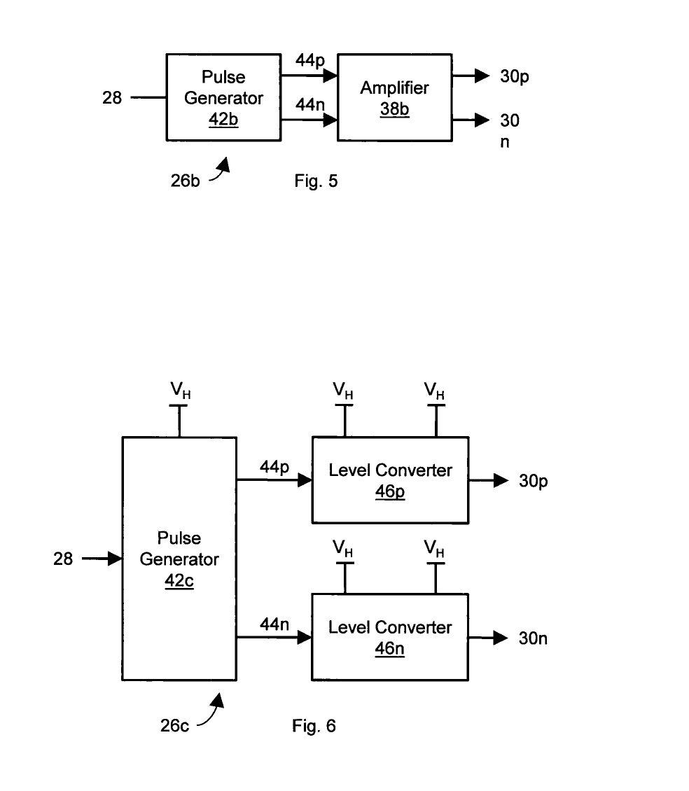

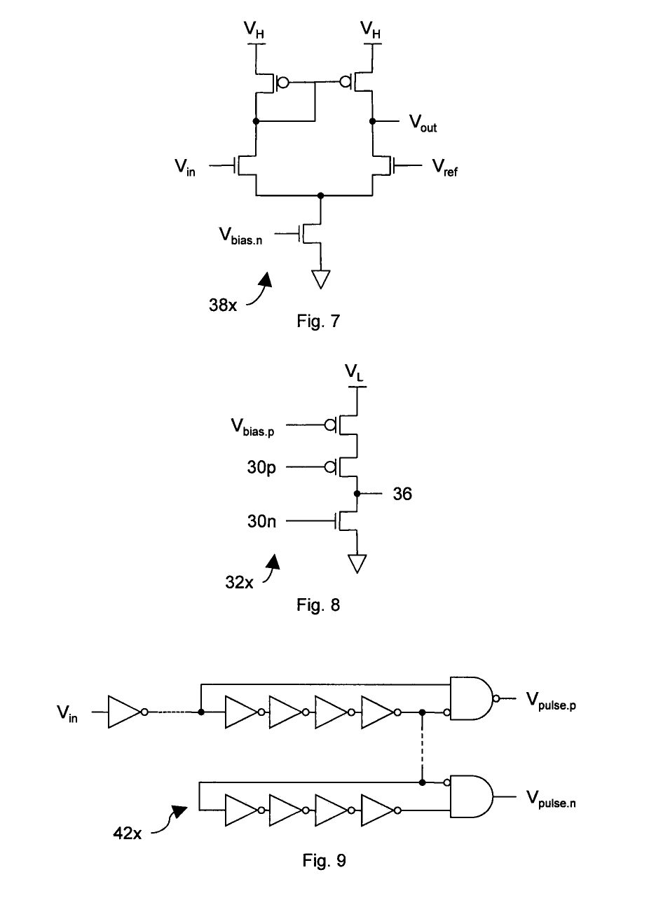

Shown in FIG. 5 is one other embodiment of the amplification element 26 constructed in accordance with our disclosure. In this embodiment, a pulse generator 42b is adapted to receive the oscillator output on amplification input 28, and to generate positive pulsed output 44p and negative pulsed output 44n. Preferably, each positive pulsed output 44p is substantially in phase with a respective positive phase of the oscillator output on amplification input 28, and each negative pulsed output 44n is substantially in phase with a respective negative phase of the oscillator output on amplification input 28. An amplifier 38b receives both the positive pulsed output 44p and negative pulsed output 44n, and generates, respectively, positive pulsed output 30p and negative pulsed output 30n. Typically, amplifier 38b will be instantiated as a matched pair of single-input/single-output amplifiers (see, below, FIG. 7).

Shown in FIG. 6 is yet another embodiment of the amplification element 26 constructed in accordance with our disclosure. In this embodiment, a pulse generator 42c is adapted to receive the oscillator output on amplification input 28, and to generate positive pulsed output 44p and negative pulsed output 44n. Preferably, each positive pulsed output 44p is substantially in phase with a respective positive phase of the oscillator output on amplification input 28, and each negative pulsed output 44n is substantially in phase with a respective negative phase of the oscillator output on amplification input 28. A positive level converter 46p receives the positive pulsed output 44p, and generates the positive pulsed output 30p. A negative level converter 46n receives the negative pulsed output 44p, and generates the negative pulsed output 30n. As will be known to those skilled in the art, voltage level conversion or voltage shifting can be accomplished using any of a number of circuit instantiations.

By way of example, we have illustrated in FIG. 7 an amplifier circuit 38x that we believe to be particularly suitable for use in our amplification elements.

By way of example, we have illustrated in FIG. 8 a driver circuit 32x that we believe to be particularly suitable for use in our driver elements.

By way of example, we have illustrated in FIG. 9 a pulse generator circuit 42x that we believe to be particularly suitable for use in our pulse generation elements.

Other embodiments of our disclosure are fully and completely disclosed in the Parent Provisional. In addition, additional aspects relating to the operational characteristics, design goals and performance achievements of specific embodiments of our disclosure may also be found in the Parent Provisional. We intend that the entire subject matter set forth in the Parent Provisional be incorporated herein in its entirety, and that the appended claims cover all such subject matter including, in particular, the embodiments disclosed therein.

Thus it is apparent that we have provided an improved method and apparatus for an ultra-low power oscillation driver circuit and method, the performance being generally comparable to the best prior art techniques while consuming substantially less power than known implementation of such prior art techniques. Therefore, we intend that our disclosure encompass all such variations and modifications as fall within the scope of the appended claims.

What we claim is:

1. A driver circuit for an oscillation element having an oscillator input and an oscillator output, the driver circuit comprising:
an amplification element having:
an amplification input adapted to be coupled to the oscillator output; and
an amplification output; and
a driver element having:
a driver input coupled to the amplification output; and
a driver output adapted to be coupled to the oscillator input.

2. The driver circuit of claim 1 wherein:
the driver element generates a driver output signal on the driver output in a first voltage domain; and
the amplification element generates an amplification output signal on the amplification output in a second voltage domain higher than the first voltage domain.

3. The driver circuit of claim 1 wherein the amplification element receives the oscillator output in a first voltage domain and generates the amplification output in a second voltage domain higher than the first voltage domain.

4. The driver circuit of claim 1 wherein:
the amplification element is further characterized as comprising a pulse generator having:
an input comprising the amplification input;
a first pulsed output; and
a second pulsed output; and
the driver element is further characterized as having:
a first driver input coupled to the first pulsed output; and
a second driver input coupled to the second pulsed output.

5. The driver circuit of claim 4 wherein the amplification element receives the oscillator output in a first voltage domain and generates the first and second pulsed outputs in a second voltage domain higher than the first voltage domain.

6. The driver circuit of claim 5 wherein the amplification element receives the oscillator output comprising positive and negative phases, and provides the first and second pulsed outputs, the first pulsed output being substantially in phase with the positive phase and the second pulsed output being substantially in phase with the negative phase.

7. The driver circuit of claim 4 wherein the amplification element receives the oscillator output comprising positive and negative phases, and provides the first and second pulsed outputs, the first pulsed output being substantially in phase with the positive phase and the second pulsed output being substantially in phase with the negative phase.

8. The driver circuit of claim 4 wherein the amplification element is further characterized as comprising:
an amplifier having:
an amplifier input comprising the amplification input; and
an amplifier output; and
a pulse generator having:
a generator input coupled to the amplifier output;
a first generator output comprising the first pulsed output; and
a second generator output comprising the second pulsed output.

9. The driver circuit of claim 4 wherein the amplification element is further characterized as comprising:
a pulse generator having:
a generator input comprising the amplification input;
a first generator output; and
a second generator output;
a first amplifier having:
a first amplifier input coupled to the first generator output; and
a first amplifier output comprising the first pulsed output; and
a second amplifier having:
a second amplifier input coupled to the second generator output; and
a second amplifier output comprising the second pulsed output.

10. The driver circuit of claim 9 wherein the first and second amplifiers, respectively, receive the first and second generator outputs in a first voltage domain and generate the first and second pulsed outputs in a second voltage domain higher than the first voltage domain.

11. The driver circuit of claim 4 wherein the first and second pulsed outputs are substantially non-overlapping.

12. A method for driving an oscillation element adapted to receive an oscillator input signal and to generate an oscillator output signal, the method comprising the steps of:
receiving the oscillator output signal;
generating an amplified output signal in response to the received oscillator output signal; and
driving the oscillator input signal in response to the amplified oscillator output signal.

13. The method of claim 12 wherein:
the oscillator input signal is driven in a first voltage domain; and
the amplified output signal is generated in a second voltage domain higher than the first voltage domain.

14. The method of claim 12 wherein the oscillator output signal is received in a first voltage domain, and the amplified output signal is generated in a second voltage domain higher than the first voltage domain.

15. The method of claim 12 wherein:
the generating step is further characterized as:
generating a positive phase pulse in response to a positive phase of the oscillator output; and
generating a negative phase pulse in response to a negative phase of the oscillator output; and
the driving step is further characterized as:
driving a positive phase of the oscillator input in response to the positive phase pulse; and
driving a negative phase of the oscillator input in response to the negative phase pulse.

16. The method of claim 15 wherein the oscillator output signal is received in a first voltage domain, and the phase pulses are generated in a second voltage domain higher than the first voltage domain.

17. The method of claim 15 wherein the positive and negative phase pulses are substantially non-overlapping.

18. A method for driving an oscillation element adapted to receive an oscillator input signal and to generate an oscillator output signal, the method comprising the steps of:
receiving the oscillator output signal;
generating, in response to the received oscillator output, a positive phase pulse, and a negative phase pulse; and
driving the oscillator input signal in response to the phase pulses.

19. The method of claim 18 wherein the oscillator output signal is received in a first voltage domain, and the phase pulses are generated in a second voltage domain higher than the first voltage domain.

20. The method of claim 18 wherein the positive and negative phase pulses are substantially non-overlapping.
